(19) United States
(12) Patent Application Publication
(10) Pub. No.: US 2026/0190337 A1
(43) Pub. Date: Jul. 2, 2026

(54) SEMICONDUCTOR MEMORY DEVICE AND METHOD FOR FORMING THE SAME

(71) Applicant: Winbond Electronics Corp., Taichung City (TW)

(72) Inventors: Jian-Sheng CHEN, Taichung City (TW); Ming-Hung LAI, Taichung City (TW); Yu-Shu CHENG, Taichung City (TW); Kuo-Lung LIN, Taichung City (TW)

(21) Appl. No.: 19/353,322

(22) Filed: Oct. 8, 2025

(30) Foreign Application Priority Data
Dec. 27, 2024 (TW) 113151056

(51) Int. Cl. H10B 41/30; H10B 41/42

(52) U.S. Cl. CPC H10B 41/30; H10B 41/42

(57) ABSTRACT

A semiconductor memory device is provided and includes a substrate and stacked structures disposed on a memory cell region of the substrate. Each stacked structure includes a gate stack, a capping layer stack, first and second spacers, and a first protection layer. The capping layer stack is disposed on the gate stack. The first gate spacer includes a vertical portion covering sidewalls of the gate stack and the capping layer stack and a horizontal portion extending laterally from the bottom of the vertical portion. The second spacer covers the sidewall of the vertical portion. The first protection layer covers the upper surface of the capping layer stack and a sidewall of the horizontal portion.

### CROSS REFERENCE TO RELATED APPLICATIONS

This application claims priority of Taiwan Patent Application No. 113151056, filed on Dec. 27, 2024, and entitled “SEMICONDUCTOR MEMORY DEVICE AND METHOD FOR FORMING THE SAME”, the entirety of which is incorporated by reference herein.

### BACKGROUND OF THE INVENTION

### Field of the Invention

The invention relates to semiconductor structure and in particular to a semiconductor memory device capable of improving data retention and a method for forming the same.

### Description of the Related Art

As semiconductor technology continues to advance, the size of semiconductor memory devices is becoming smaller and smaller. As a result, the integration density of semiconductor memory devices is being greatly improved, thereby improving the performance of memory devices and the functionality of electronic products.

However, as the size of semiconductor memory devices decreases, the line width and spacing of gates in transistors are also being greatly reduced, meaning that the manufacturing process for semiconductor memory devices is facing many new challenges. For example, although each gate structure in the memory cell region includes multiple gate spacers, plasma charges and mobile ions can easily cause damage to the oxide layer and enter the memory cell region, causing memory data loss.

### BRIEF SUMMARY OF THE INVENTION

In some embodiments, a semiconductor memory device is provided. The semiconductor memory device includes a substrate and a plurality of stacked structures. The stacked structures are disposed on the memory cell region of the substrate, and each of the stacked structures includes a gate stack, a capping layer stack, a first spacer, a second spacer, a first protection layer, and a second protection layer. The capping layer stack is disposed on the gate stack. The first spacer has a vertical portion covering a sidewall of the gate stack and a sidewall of the capping layer stack, and a horizontal portion extending laterally from the bottom of the vertical portion. The second spacer covers a sidewall of the vertical portion. The first protection layer extends from the top of the second spacer and covers the upper surface of the capping layer stack, and the second protection layer is adjacent to the bottom of the second spacer and covers a sidewall of the horizontal portion.

In some embodiments, a method for forming a semiconductor memory device is provided. The method includes forming a plurality of stacked structures on a memory cell region of a substrate. Each of the stacked structures includes a gate stack, a capping layer stack, a first spacer and a second spacer. The capping layer stack is formed on the gate stack. The first spacer has a vertical portion covering a sidewall of the gate stack and a sidewall of the capping layer stack, and a horizontal portion extending laterally from the bottom of the vertical portion, and the second spacer covers a sidewall of the vertical portion. The method also includes performing a surface treatment to form a first protection layer and a second protection layer. The first protection layer extends from the top of the second spacer and covers the upper surface of the capping layer stack, and the second protection layer is adjacent to the bottom of the second spacer and covers a sidewall of the horizontal portion.

### BRIEF DESCRIPTION OF THE DRAWINGS

FIG. 1 is a plan view of an intermediate manufacturing stage of a semiconductor memory device according to some embodiments.

FIGS. 2A, 2B, 2C, 2D and 2E show cross-sectional views of semiconductor memory devices at various manufacturing stages according to some embodiments, in which FIG. 2A is a cross-sectional view taken along line 2-2′ in FIG. 1 according to some embodiments.

FIG. 3 is a cross-sectional view of a semiconductor memory device having the structure shown in FIG. 2E according to some embodiments.

### DETAILED DESCRIPTION OF THE INVENTION

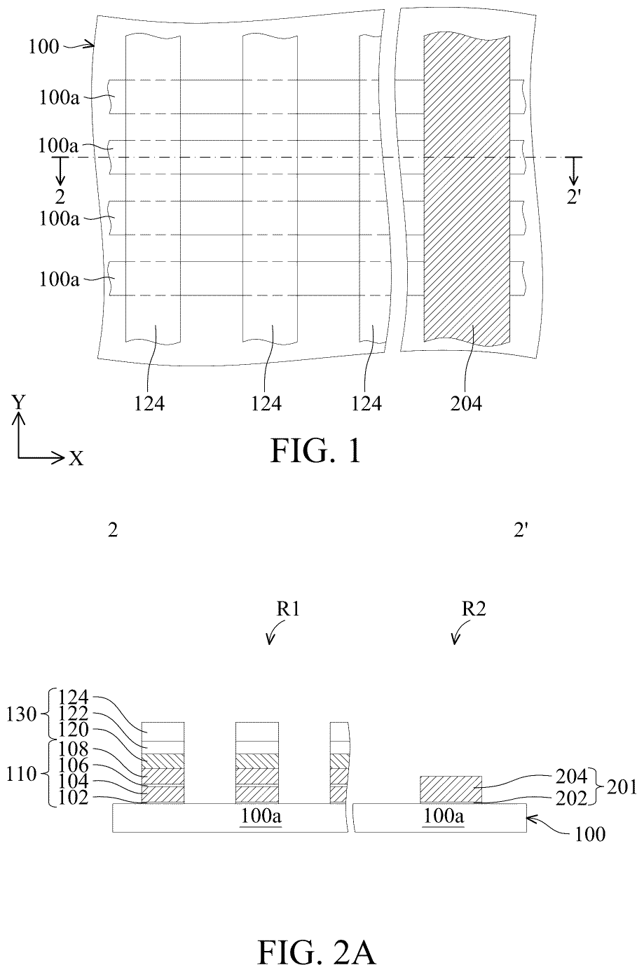

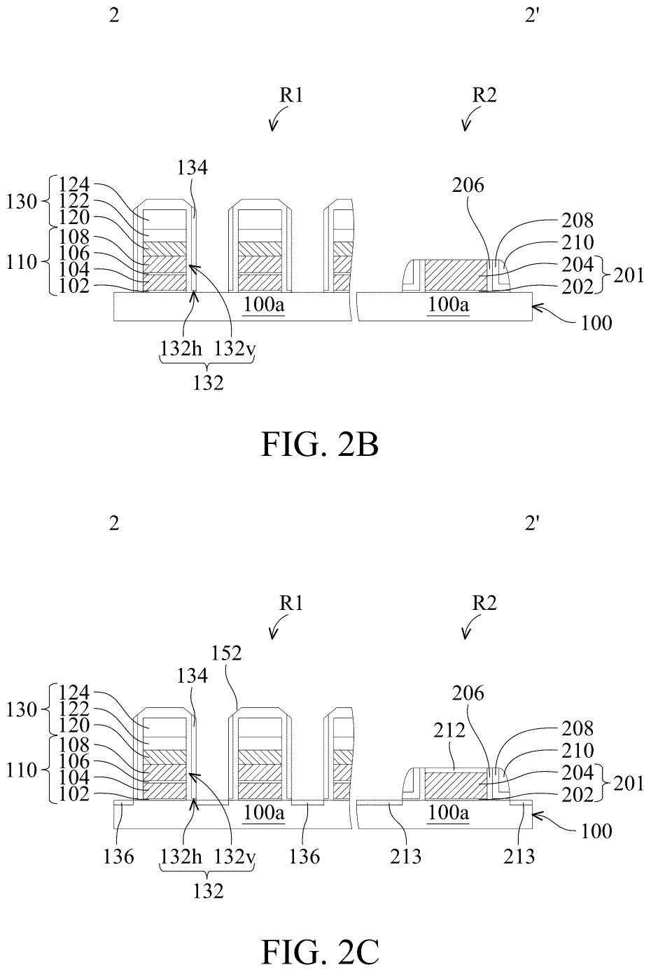

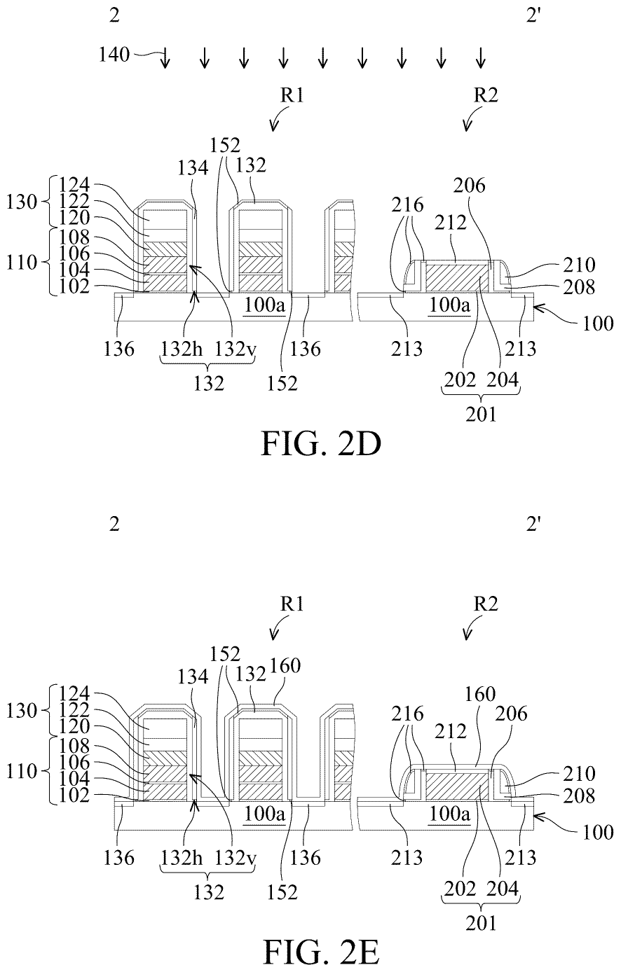

FIG. 1 is a plan view of an intermediate manufacturing stage of a semiconductor memory device according to some embodiments. FIGS. 2A, 2B, 2C, 2D and 2E are cross-sectional views of semiconductor memory devices at various manufacturing stages according to some embodiments. Referring to FIGS. 1 and 2A (which are cross-sectional views taken along line 2-2′ in FIG. 1 according to some embodiments), a substrate 100 having a memory cell region R1 and a peripheral region R2 is provided. The memory cell region R1 and the peripheral region R2 have active regions 100a defined by isolation regions (not shown). For example, the isolation region is a shallow trench isolation region. As shown in FIG. 1, active regions 100a extend along the X direction and are arranged parallel to each other. In one embodiment, the substrate 100 may be a silicon semiconductor substrate, a silicon-on-insulator (SOI) substrate, or other suitable semiconductor substrates (e.g., a gallium arsenide semiconductor substrate, a gallium nitride semiconductor substrate, or a germanium silicide semiconductor substrate). In the embodiment, the semiconductor substrate 100 is a silicon semiconductor substrate.

Next, as shown in FIG. 2A, gate stacks 110 and capping layer stacks 130 located thereon are formed on the memory cell region R1 of the substrate 100. Furthermore, gate stacks 201 are formed on the peripheral region R2 of the substrate 100. As shown in FIG. 1, the gate stack 110 (and the overlying capping layer stack 130) and the gate stack 201 each extend along the Y direction and cross the active regions 100a. In one embodiment, the Y direction is perpendicular or orthogonal to the X direction.

Referring again to FIG. 2A again, in the memory cell region R1, each gate stack 110 includes a tunnel dielectric layer 102, a gate layer 104, an inter-gate dielectric layer 106, and a gate layer 108 successively formed from bottom to top. The tunnel dielectric layer 102 is formed on the upper surface of the active region 100a. The tunnel dielectric layer 102 may be made of silicon dioxide. The gate layer 104 may be a strip-shaped structure crossing the active regions 100a and formed on the tunneling dielectric layer 102. The gate layer 104 (which is sometimes also referred to as a floating gate layer) includes a conductive material, such as doped polysilicon, undoped polysilicon, or a combination thereof. The inter-gate dielectric layer 106 is formed on the gate layer 104 and may be a multi-layer structure including a silicon oxide layer/silicon nitride layer/silicon oxide layer (oxide-nitride-oxide, ONO). The gate layer 108 (which is sometimes also referred to as a control gate layer) is formed on the inter-gate dielectric layer 106 and includes a conductive material, such as doped polysilicon, undoped polysilicon, or a combination thereof.

In one embodiment, the capping layer stack 130 formed on each gate stack 110 includes a conductive capping layer 120, an insulating capping layer 122, and an insulating capping layer 124 successively formed from bottom to top. In one embodiment, the conductive capping layer 120 may include metal (e.g., tungsten, cobalt, or the like), metal silicide (e.g., tungsten silicide, cobalt silicide, or the like), or a combination thereof or other suitable conductive materials. In the embodiment, the conductive capping layer 120 may be made of tungsten metal.

In one embodiment, the insulating capping layer 122 and the insulating capping layer 124 are made of different insulating materials. For example, the insulating capping layer 122 may include a nitrogen-containing dielectric material, such as silicon nitride, silicon carbonitride, silicon oxynitride, or the like, or a combination thereof. The insulating capping layer 124 may include a nitrogen-free dielectric material such as silicon oxide, silicon carbide, silicon oxycarbide, or the like, or a combination thereof. In the embodiment, the insulating capping layer 122 may be made of silicon nitride (e.g., SiN or Si₃N₄), and the insulating capping layer 124 may be made of silicon oxide (e.g., SiO₂).

Referring again to FIG. 2A again, in the peripheral region R2, the gate stack 201 includes a gate dielectric layer 202 and a gate layer 204 successively formed from bottom to top. In one embodiment, the gate dielectric layer 202 may include a material that is similar to or the same as that of the tunnel dielectric layer 102. Furthermore, the gate dielectric layer 202 and the tunnel dielectric layer 102 can be fabricated during the same process. Alternatively, the gate dielectric layer 202 and the tunnel dielectric layer 102 may be fabricated during separate processes. In the embodiment, the gate layer 204 may include a material similar to or the same as that of the gate layer 104 or the gate layer 108. Furthermore, the gate layer 204 and the gate layer 104 can be fabricated during the same process. Alternatively, the gate layer 204 and the gate layer 104 may be fabricated during separate processes. In the embodiment, the gate layer 204 and the gate layer 104 can be manufactured during separate processes, so that the gate layer 204 and the gate layer 104 have different sizes. For example, the thickness and width of the gate layer 204 are greater than the thickness and width of the gate layer 104.

Referring to FIG. 2B, a first protection structure is formed on the memory cell region R1 of the substrate 100. Furthermore, a second protection structure is formed on the peripheral region R2 of the substrate 100. The first protection structure covers two opposite sidewalls of the corresponding gate stack 110, and covers two opposite sidewalls and the upper surface of the corresponding capping layer stack 130. The second protection structure covers two opposite sidewalls of the gate stack 201.

In one embodiment, the first protection structure is formed by successively utilizing a conformal deposition process (e.g., a chemical vapor deposition process, an atomic layer deposition process, or a suitable deposition process) and an etching process (e.g., a dry etching process). Similarly, the second protection structure may also be formed by sequentially utilizing the conformal deposition process and the etching process.

In one embodiment, the first protection structure includes a first spacer 132 and a second spacer 134 from the inside to the outside. The first spacer 132 and the second spacer 134 are formed by successively conformingly depositing two insulating layers (not shown) of different materials to cover the upper surface of the insulating capping layer 124 and two opposite sidewalls of the gate stack 110 and two opposite sidewalls of the capping layer stack 130, and then etching the two insulating layers. As shown in FIG. 2B, in one embodiment, the first spacer 132 covers the upper surface of the insulating capping layer 124 and has a vertical portion 132v covering the sidewalls of the gate stack 110 and the sidewalls of the capping layer stack 130 and a horizontal portion 132h extending laterally from the bottom of the vertical portion 132v. The second spacer 134 is disposed on the horizontal portion 132h of the first spacer 132 and covers the sidewall of the vertical portion 132v of the first spacer 132. Furthermore, the second spacer 134 exposes a portion of the first spacer 132 that covers the upper surface of the insulating capping layer 124 and the sidewall of the horizontal portion 132h of the first spacer 132. In one embodiment, the first spacer 132 and the insulating capping layer 124 may be made of the same material, such as a nitrogen-free dielectric material. The nitrogen-free dielectric material may include silicon oxide, silicon carbide, or silicon oxycarbide or the like, or a combination thereof. The second spacer 134 and the insulating capping layer 122 are made of the same material, such as a nitrogen-containing dielectric material. The nitrogen-containing dielectric material may include silicon nitride, silicon carbonitride, silicon oxynitride, or the like, or a combination thereof. In the embodiment, the first spacer 132 may be made of silicon oxide (e.g., SiO₂), and the second spacers 134 may be made of silicon nitride (e.g., SiN or Si₃N₄).

In one embodiment, the second protection structure includes a first spacer 206, a second spacer 208, and a third spacer 210 from the inside to the outside. The first spacer 206, the second spacer 208 and the third spacer 210 are formed by successively conformingly depositing three insulating layers (not shown) to cover the upper surface and two opposite sidewalls of the gate layer 204, and then performing an etching process on the three insulating layers. As shown in FIG. 2B, in one embodiment, the first spacer 206 has a vertical portion covering the sidewall of the gate stack 201 and a horizontal portion extending laterally from the bottom of the vertical portion. The second spacer 208 has a vertical portion covering the sidewall of the vertical portion of the first spacer 206 and a horizontal portion covering the upper surface of the horizontal portion of the first spacer 206. The third spacer 210 is formed on the horizontal portion of the second spacer 208 and covers the sidewall of the vertical portion of the second spacer 208. The first spacer 206, the second spacer 208, and the third spacer 210 expose the upper surface of the gate layer 204. In one embodiment, the first spacer 206 and the third spacer 210 may include the same material that is different than the material of the second spacer 208. In one embodiment, the first spacer 206 and the third spacer 210 may include a nitrogen-free dielectric material, such as silicon oxide, silicon carbide, silicon oxycarbide, or the like, or a combination thereof. The second spacer 208 may include a nitrogen-containing dielectric material, such as silicon nitride, silicon carbonitride, silicon oxynitride, or the like, or a combination thereof. In the embodiment, the first spacer 206 and the third spacer 210 may be made of silicon oxide (e.g., SiO₂), and the second spacer 208 may be made of silicon nitride (SiN or Si₃N₄).

Referring to FIG. 2C, after the first protection structure and the second protection structure are formed, the portion of the upper surface of the active region 100a of the substrate 100 that is uncovered by the gate stacks 110 and 201 and the first and second protection structures, and the upper surface of the gate layer 204 are exposed. Afterwards, a wet cleaning process may be optionally performed on the exposed upper surface of the active region 100a and the exposed upper surface of the gate layer 204 to remove the native oxide layer or any undesired impurities formed on these upper surfaces. Next, metal silicide layers 136, 212, and 213 are correspondingly formed on these upper surfaces. The metal silicide layers 136, 212, and 213 may include tungsten silicide, cobalt silicide, or the like, or a combination thereof. In the embodiment, the metal silicide layers 136, 212, and 213 may be made of cobalt silicide.

Referring to FIG. 2D, after the metal silicide layers 136, 212, and 213 are formed, a surface treatment 140 is performed to form a protection layer 152 in the memory cell region R1 and a protection layer 216 in the peripheral region R2.

In one embodiment, the protection layer 152 in the memory cell region R1 covers the portion of the first spacer 132 that is above the upper surface of the insulating capping layer 124 and exposed from the second spacer 134. Meanwhile, the protection layer 152 also covers the sidewall of the horizontal portion 132h of the first spacer 132 below the bottom of the second spacer 134.

In one embodiment, the protection layer 216 in the peripheral region R2 covers the upper surface of the first spacer 206. Furthermore, the protection layer 216 covers the sidewall of the third spacer 210 and the sidewall of the horizontal portion of the first spacer 206.

In one embodiment, the surface treatment 140 is a self-aligned nitridation process. The nitridation process may include a decoupled plasma nitridation process, a nitrogen atmosphere nitridation process, a nitrogen plasma nitridation process or other suitable nitridation processes. As a result, the protection layers 152 and 216 that are formed are made of silicon oxynitride and/or silicon nitride.

The protection layers 152 and 216 made of silicon oxynitride and/or silicon nitride and the second spacers 134 and 208 made of silicon nitride serve as barrier layers to effectively prevent plasma charges and/or migrating ions from damaging the first spacers 132 and 206 made of silicon oxide and entering the charge storage structure of the semiconductor memory device.

Referring to FIG. 2E, a protection layer 160 is conformally formed on the surface of the structure shown in FIG. 2D, so as to cover the protection layers 152 and 216, the second spacers 134 and 208, and the metal silicide layers 136, 212, and 213. In the memory cell region R1, since the thickness of the protection layer 152 formed by the surface treatment (e.g., nitridation treatment) is smaller than the thickness of the first spacer 132 and the second spacer 134, the protection layer 160 that is formed can provide protection for the protection layer 152, and therefore the protection layer 152 is not damaged in the subsequent etching process or planarization process (e.g., chemical mechanical polishing process) and lose the function of blocking plasma charges or of migrating ions. In one embodiment, the protection layer 160 is made of a different material than the protection layer 152 and the second spacer 134. In one embodiment, the protection layer 160 is made of silicon oxide, such as tetraethoxysilane (TEOS) oxide.

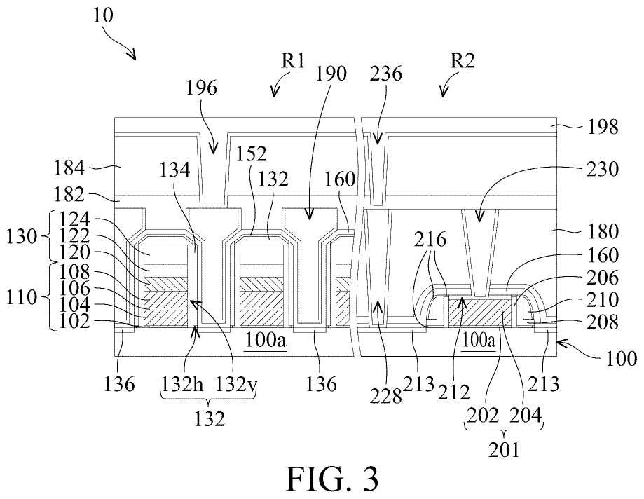

Referring to FIG. 3, which shows a cross-sectional view of a semiconductor memory device 10 having the structure shown in FIG. 2E according to some embodiments. Elements in FIG. 3 that are the same as those in FIG. 2 are labeled with the same reference numbers as in FIG. 2 and are not described again for brevity. In one embodiment, the semiconductor memory device 10 includes an interlayer dielectric layer 180, an etch stop layer 182, and an inter-metal dielectric layer 184 that are successively stacked on the structure shown in FIG. 2E. The interlayer dielectric layer 180 and the inter-metal dielectric layer 184 may include the same or similar dielectric material, such as silicon oxide, undoped silicate glass, or an oxide-based dielectric material formed of doped silicon oxide (e.g., borophosphosilicate glass, phosphosilicate glass, boron-doped silica glass, low-k dielectric materials, other suitable dielectric materials, or combinations thereof. The etch stop layer 182 may include silicon nitride, silicon oxynitride, silicon carbonitride, silicon carbide, or other suitable dielectric materials, or combinations thereof.

In one embodiment, the semiconductor memory device 10 further includes an interconnect structure formed in and on the interlayer dielectric layer 180, the etch stop layer 182, and the inter-metal dielectric layer 184. In one embodiment, the interconnect structure includes source/drain contacts (which are sometimes also referred to as contact plugs) 190 and gate contacts (not shown) in the interlayer dielectric layer 180 of the memory cell region R1, and source/drain contacts 228 and a gate contact 230 in the interlayer dielectric layer 180 of the peripheral region R2. The source/drain contacts 190 are electrically connected to the source/drain regions through the metal silicide layer 136. The gate contact 230 is electrically connected to the gate layer 204 through the metal silicide layer 212. The source/drain contacts 228 are electrically connected to the source/drain regions through the metal silicide layer 213. In one embodiment, the interconnect structure further includes a bit line 198 on the inter-metal dielectric layer 184 and electrically connected to corresponding source/drain contacts 190 and 228 by via plugs 196 and 236, respectively, in which the via plugs 196 and 236 penetrate the inter-metal dielectric layer 184 and the underlying etch stop layer 182.

According to the foregoing embodiments, the exposed surface of the first spacer that is made of silicon oxide and formed in the stacked structure (including the gate stack, the capping layer stack, and the gate spacer) of the memory cell region is covered with a protection layer serving as a barrier layer. Therefore, the gate spacer made of silicon oxide can be effectively prevented from being damaged by the plasma charges and/or migrating ions and entering the charge storage structure of the semiconductor memory device. As a result, the reduction of device performance caused by the data loss in the semiconductor memory device can be avoided. According to the foregoing embodiments, the protection layer serving as a barrier layer is formed by using the surface treatment (self-aligned nitridation process), which can provide better cell coverage and effectively reduce the stress caused by the protection layer, thereby reducing the chance of changes in the electrical properties of the device, compared to forming the protection layer by a deposition process. According to the foregoing embodiments, the protection layer formed by the surface treatment can simplify the manufacturing process and reduce the manufacturing cost.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device, comprising:
a substrate having a memory cell region; and
a plurality of stacked structures disposed on the memory cell region of the substrate, wherein each of the stacked structures comprises:
a gate stack;
a capping layer stack disposed on the gate stack;
a first spacer having a vertical portion covering a sidewall of the gate stack and a sidewall of the capping layer stack and a horizontal portion extending laterally from a bottom of the vertical portion;
a second spacer covering a sidewall of the vertical portion; and
a first protection layer extending upward from a top of the second spacer to cover an upper surface of the capping layer stack, and extending downward along a sidewall of the second spacer to cover a sidewall of the horizontal portion.

2. The semiconductor memory device as claimed in claim 1, wherein the capping layer stack comprises:
a first insulating capping layer; and
a second insulating cover layer disposed on the first insulating capping layer.

3. The semiconductor memory device as claimed in claim 2, wherein the capping layer stack further comprises:
a conductive capping layer disposed between the first insulating capping layer and the gate stack.

4. The semiconductor memory device as claimed in claim 2, wherein the first insulating capping layer and the second insulating capping layer are made of different materials.

5. The semiconductor memory device as claimed in claim 4, wherein the second insulating capping layer is made of silicon oxide.

6. The semiconductor memory device as claimed in claim 2, wherein the second spacer and the first insulating capping layer are made of silicon nitride, and wherein the first spacer and the second insulating capping layer are made of silicon oxide.

7. The semiconductor memory device as claimed in claim 6, wherein the first protection layer is made of silicon oxynitride.

8. The semiconductor memory device as claimed in claim 1, wherein a thickness of the first protection layer is smaller than a thickness of the second spacer.

9. The semiconductor memory device as claimed in claim 7, wherein the gate stack comprises:
a tunnel dielectric layer;
a first gate layer disposed on the tunnel dielectric layer;
a second gate layer disposed on the first gate layer; and
an inter-gate dielectric layer disposed between the first gate layer and the second gate layer.

10. The semiconductor memory device as claimed in claim 1, wherein each of the stacked structures further comprises:
a second protection layer covers the first protection layer and the second spacer, wherein the second protection layer is made of a material that is different than those of the first protection layer and the second spacer.

11. A method for forming a semiconductor memory device, comprising:
forming a plurality of stacked structures on a memory cell region of a substrate, wherein each of the stacked structures comprises:
a gate stack;
a capping layer stack formed on the gate stack;
a first spacer having a vertical portion covering a sidewall of the gate stack and a sidewall of the capping layer stack and a horizontal portion extending laterally from a bottom of the vertical portion; and
a second spacer covering a sidewall of the vertical portion; and
performing a surface treatment to form a first protection layer, wherein the first protection layer extends upward from a top of the second spacer to cover an upper surface of the capping layer stack, and extends downward along a sidewall of the second spacer to cover a sidewall of the horizontal portion.

12. The method as claimed in claim 11, further comprising:
forming a second protection layer to cover the first protection layer and the second spacer, wherein the second protection layer is made of a material different from that of the first protection layer and the second spacer.

13. The method as claimed in claim 12, wherein the second protection layer is made of silicon oxide and the first protection layer is made of silicon oxynitride.

14. The method as claimed in claim 11, wherein the capping layer stack comprises:
a first insulating capping layer;
a second insulating capping layer formed on the first insulating capping layer; and
a conductive capping layer is disposed between the first insulating capping layer and the gate stack.

15. The method as claimed in claim 14, wherein the first insulating capping layer and the second insulating capping layer are made of different materials.

16. The method as claimed in claim 14, wherein the second spacer and the first insulating capping layer are made of the same material, and wherein the first spacer and the second insulating capping layer are made of the same material.

17. The method as claimed in claim 11, wherein the gate stack comprises:
a tunnel dielectric layer;
a first gate layer formed on the tunnel dielectric layer;
a second gate layer formed on the first gate layer; and
an inter-gate dielectric layer formed between the first gate layer and the second gate layer.

18. The method as claimed in claim 11, wherein the surface treatment is a nitridation treatment.

19. The method as claimed in claim 11, further comprising:
forming a plurality of metal silicide layers on an upper surface of the substrate and between two adjacent stacked structures before performing the surface treatment.

20. The method as claimed in claim 19, further comprising:
performing a wet cleaning process on the upper surface of the substrate before forming the metal silicide layers.
